(19) United States
(12) Patent Application Publication
(10) Pub. No.: US 2013/0075892 A1
(43) Pub. Date: Mar. 28, 2013

(54) Method for Three Dimensional Integrated Circuit Fabrication

(71) Applicants: Jing-Cheng Lin, Hsin-Chu (TW); Weng-Jin Wu, Hsin-Chu (TW); Ying-Ching Shih, Taipei (TW); Jui-Pin Hung, Hsin-Chu (TW); Szu Wei Lu, Hsin-Chu (TW); Shin-Puu Jeng, Hsin-Chu (TW); Chen-Hua Yu, Hsin-Chu (TW)

(72) Inventors: Jing-Cheng Lin, Hsin-Chu (TW); Weng-Jin Wu, Hsin-Chu (TW); Ying-Ching Shih, Taipei (TW); Jui-Pin Hung, Hsin-Chu (TW); Szu Wei Lu, Hsin-Chu (TW); Shin-Puu Jeng, Hsin-Chu (TW); Chen-Hua Yu, Hsin-Chu (TW)

(73) Assignee: Taiwan Semiconductor Manufacturing Company, Ltd., Hsin-Chu (TW)

(21) Appl. No.: 13/246,553

(22) Filed: Sep. 27, 2011

(51) Int. Cl. H01L 23/48; H01L 21/50

(52) U.S. Cl. 257/737; 438/109; 257/E21.499; 257/E23.021

(57) ABSTRACT

A method for fabricating three dimensional integrated circuits comprises providing a wafer stack wherein a plurality of semiconductor dies are mounted on a first semiconductor die, forming a molding compound layer on the first side of the first semiconductor die, wherein the plurality of semiconductor dies are embedded in the molding compound layer. The method further comprises grinding a second side of the first semiconductor die until a plurality of through vias become exposed, attaching the wafer stack to a tape frame and dicing the wafer stack to separate the wafer stack into a plurality of individual packages.

### BACKGROUND

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node (e.g., shrink the process node towards the sub-20 nm node). As the demand for miniaturization, higher speed and greater bandwidth, as well as lower power consumption and latency has grown recently, there has grown a need for smaller and more creative packaging techniques of semiconductor dies.

As semiconductor technologies evolve, multi-chip wafer level package based semiconductor devices have emerged as an effective alternative to further reduce the physical size of a semiconductor chip. In a wafer level package based semiconductor device, active circuits such as logic, memory, processor circuits and the like are fabricated on different wafers and each wafer die is stacked on top of another wafer die using pick-and-place techniques. Much higher density can be achieved by employing multi-chip semiconductor devices. Furthermore, multi-chip semiconductor devices can achieve smaller form factors, cost-effectiveness, increased performance and lower power consumption.

A three-dimensional (3D) integrated circuit (IC) may comprise a top active circuit layer, a bottom active circuit layer and a plurality of inter-layers. In a 3D IC, two dies may be bonded together through a plurality of micro bumps and electrically coupled to each other through a plurality of through-substrate vias. The micro bumps and through-substrate vias provide an electrical interconnection in the vertical axis of the 3D IC. As a result, the signal paths between two semiconductor dies are shorter than those in a traditional 3D IC in which different dies are bonded together using interconnection technologies such as wire bonding based chip stacking packages. A 3D IC may comprise a variety of semiconductor dies stacked together. The multiple semiconductor dies are packaged before the wafer has been diced. The wafer level package technology has some advantages. One advantageous feature of packaging multiple semiconductor dies at the wafer level is multi-chip wafer level package techniques may reduce fabrication costs. Another advantageous feature of wafer level package based multi-chip semiconductor devices is that parasitic losses are reduced by employing micro bumps and through-substrate vias.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1-5 are cross sectional views of intermediate stages in the making of a three-dimensional (3D) integrated circuit (IC) in accordance with an embodiment;

FIGS. 6-10 are cross sectional views of intermediate stages in the making of a 3D IC in accordance with another embodiment; and

FIGS. 11-15 are cross sectional views of intermediate stages in the making of a 3D IC in accordance with yet another embodiment.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to embodiments in a specific context, a method for fabricating three-dimensional (3D) integrated circuits (ICs). The disclosure may also be applied, however, to the semiconductor fabrication of a variety of integrated circuits.

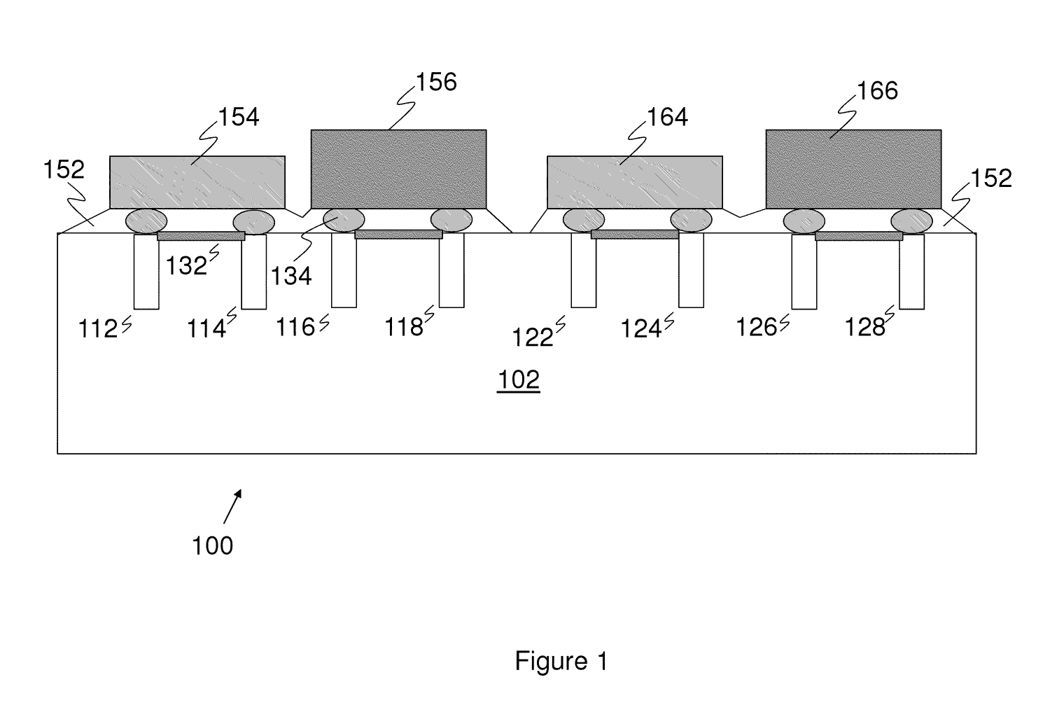

FIGS. 1-5 are cross sectional views of intermediate stages in the making of a 3D IC in accordance with an embodiment. A wafer stack 100 may comprise a wafer 102 and a plurality of semiconductor dies mounted on top of the wafer 102. In accordance with an embodiment, the wafer 102 is a silicon wafer. As shown in FIG. 1, the plurality of semiconductor dies may include a first semiconductor die 154, a second semiconductor die 156, a third semiconductor die 164 and a fourth semiconductor die 166. The wafer 102 may be a standard wafer having a thickness more than 100 um. In accordance with an embodiment, the wafer 102 may be of a thickness of about 770 um. The wafer 102 may comprise a plurality of integrated circuits (not shown), each of which may comprise various layers such as active circuit layers, substrate layers, inter-layer dielectric (ILD) layers and inter-metal dielectric (IMD) layers (not shown). The wafer 102 may further comprise a plurality of micro bumps 134 formed between the wafer 102 and the plurality of semiconductor dies (e.g., the first semiconductor die 154). Furthermore, the connections of the plurality of micro bumps 134 may be redistributed through a redistribution layer 132 formed on top of the wafer 102.

The wafer 102 may further comprise a plurality of through vias. In some embodiments, the through vias are through-substrate vias (TSVs) or through-silicon vias (TSVs), such as TSVs 112, 114, 116, 118, 122, 124, 126 and 128. The active circuit layers (not shown) of the wafer 102 may be coupled to micro bumps 134 and/or one or more of the plurality of TSVs (e.g., TSV 112). The active circuit layers are further connected to the first semiconductor die 154, the second semiconductor die 156, the third semiconductor die 164 and the fourth semiconductor die 166 through the plurality of micro bumps 134.

An underfill material 152 may be formed in the gap between the wafer 102 and the plurality of semiconductor dies (e.g., the first semiconductor die 154) mounted on top of the wafer 102. In accordance with an embodiment, the underfill material 152 may be an epoxy, which is dispensed at the gap between the wafer 102 and the first semiconductor die 154. The epoxy may be applied in a liquid form, and may harden after a curing process. In accordance with another embodiment, the underfill layer 152 may be formed of curable materials such as polymer based materials, resin based materials, polyimide, epoxy and any combinations of thereof. The underfill layer 152 can be formed by a spin-on coating process, dry film lamination process and/or the like. An advantageous feature of having an underfill material (e.g., underfill material 152) is that the underfill material 152 helps to prevent the micro bumps 134 from cracking. In addition, the underfill material 152 may help to reduce the mechanical and thermal stresses during the fabrication process of the wafer stack 100.

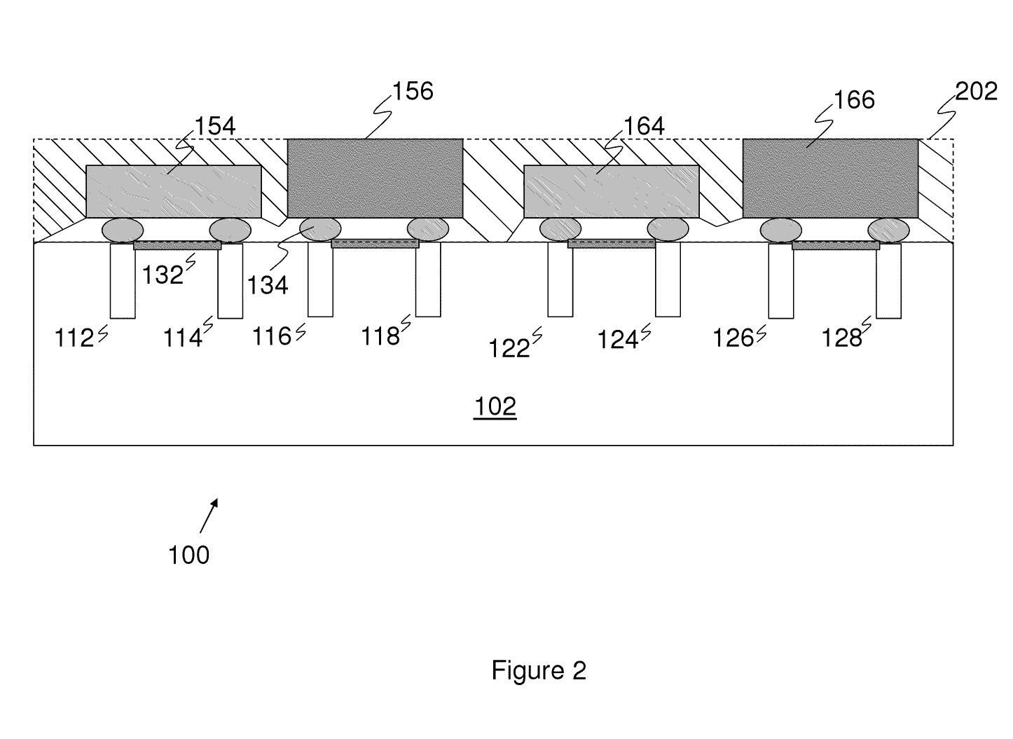

FIG. 2 illustrates a cross sectional view of a 3D IC structure having a molding compound layer formed on top of the wafer 102. As shown in FIG. 2, the first semiconductor die 154, the second semiconductor die 156, the third semiconductor die 164 and the fourth semiconductor die 166 are embedded in the molding compound layer 202. The molding compound layer 202 may be formed of curable materials such as polymer based materials, resin based materials, polyimide, epoxy and any combinations of thereof. The molding compound layer 202 can be formed by a spin-on coating process, an injection molding process and/or the like. In order to reliably handle the wafer 102 and the semiconductor dies (e.g., the first semiconductor die 154) mounted on top of the wafer 102 during process steps such as dicing the wafer stack 100 into separate chip packages, the molding compound layer 202 is employed to keep the wafer 102 and the semiconductor dies on top of wafer from cracking, bending, warping and/or the like.

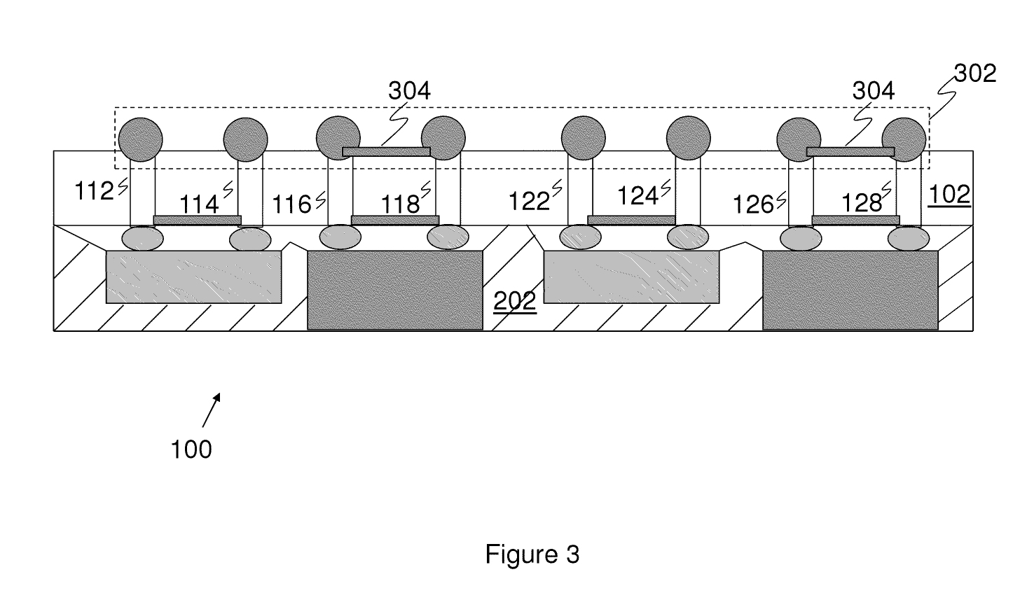

FIG. 3 illustrates a process of backside grinding. The backside of the wafer 102 undergoes a thinning process. The thinning process can employ a mechanical grinding process, a chemical polishing process, an etching process or the like. By employing the thinning process, the backside of the wafer 102 can be ground so that the wafer 102 may have a thickness of approximately sub-100 um. In accordance with an embodiment, the thickness of the wafer 102 may be reduced to a range from about 20 um to about 50 um. It should be noted that by grinding the wafer 102 to a thickness as low as 20 um, such a thin wafer may enable small via feature size such as via diameter and depth. An advantageous feature of forming small TSVs is that the performance and power consumption of the wafer stack 100 can be further improved.

Alternatively, the thickness of the wafer 102 may be ground until the embedded ends of the TSVs (e.g., TSV 112) become exposed. Subsequently, a redistribution layer 304 is formed on top of the newly ground backside of the wafer 102. Furthermore, a plurality of bumps 302 are formed on top of the exposed ends of the TSVs. It should be noted the bumps 302 may be formed somewhere other than the exposed ends of the TSVs and reconnected with the TSVs (e.g., TSV 116) through the redistribution layer 304.

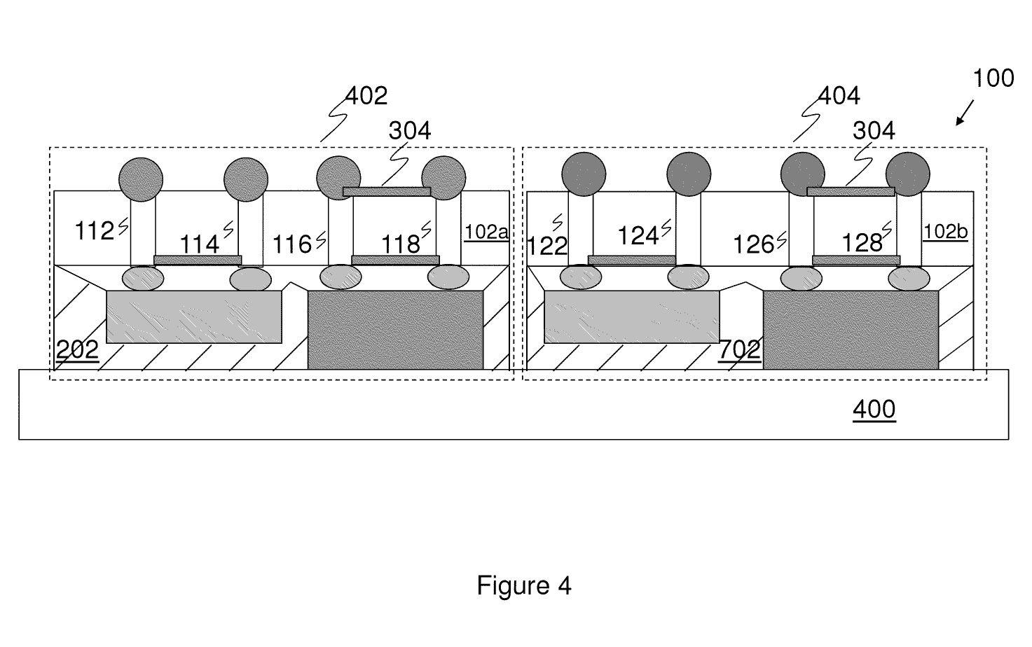

FIG. 4 illustrates a process of attaching the wafer stack 100 to a tape frame 400. The wafer stack 100 is mounted on top of a tape frame 400. The tape frame 400 may comprise a carrier on which a temporary adhesive is coated. The bonding process may be performed in a chamber in which the wafer stack 100 is bonded on top of the tape frame 400. The bonding process of attaching a wafer stack to a tape frame is well known in the art, and hence is not discussed in further detail herein.

FIG. 4 further illustrates a process of separating the wafer stack 100 into a plurality of individual packages using a dicing process. As shown in FIG. 4, a plurality of individual packages such as a first package 402 and a second package 404 are formed by sawing the wafer stack 100 into individual packages. Each individual package may include at least one semiconductor die bonded on a die (e.g., die 102a). The dicing process is well known in the art, and hence is not discussed in detail herein. It should be noted while FIG. 4 shows the side having a plurality of semiconductor dies of the wafer stack 100 (opposite to the flip chip bump side) is attached to the tape frame 400, and then a sawing process is performed, a person skilled in the art will recognize that there can be many variations of an embodiment of this disclosure. For example, the flip chip bump side of the wafer stack 100 can be attached to the tape frame 400. A sawing process can also be performed from the semiconductor die side of the wafer stack 100.

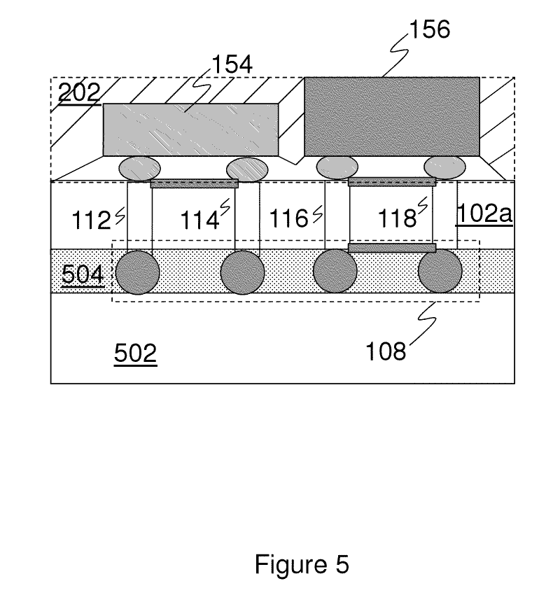

FIG. 5 illustrates a cross sectional view of the 3D IC after the dicing process. As shown in FIG. 5, the packages 402 and 404 (not shown but illustrated in FIG. 4) have been removed from the tape frame 400 (not shown) by employing a pick-and-place process. The pick-and-place process is well known in the art, and hence is not discussed in further detail to avoid repetition. The surfaces of both the first package 402 and the second 404 may be further polished by a chemical solvent, and then are flipped again. Subsequently, the individual packages such as the first package 402 are mounted on a substrate 502 to form a 3D IC. In accordance with an embodiment, the substrate 502 may be an organic based substrate. Furthermore, in order to reduce mechanical and thermal stresses, an underfill material 504 is formed in the gap between the first package 402 and the substrate 502.

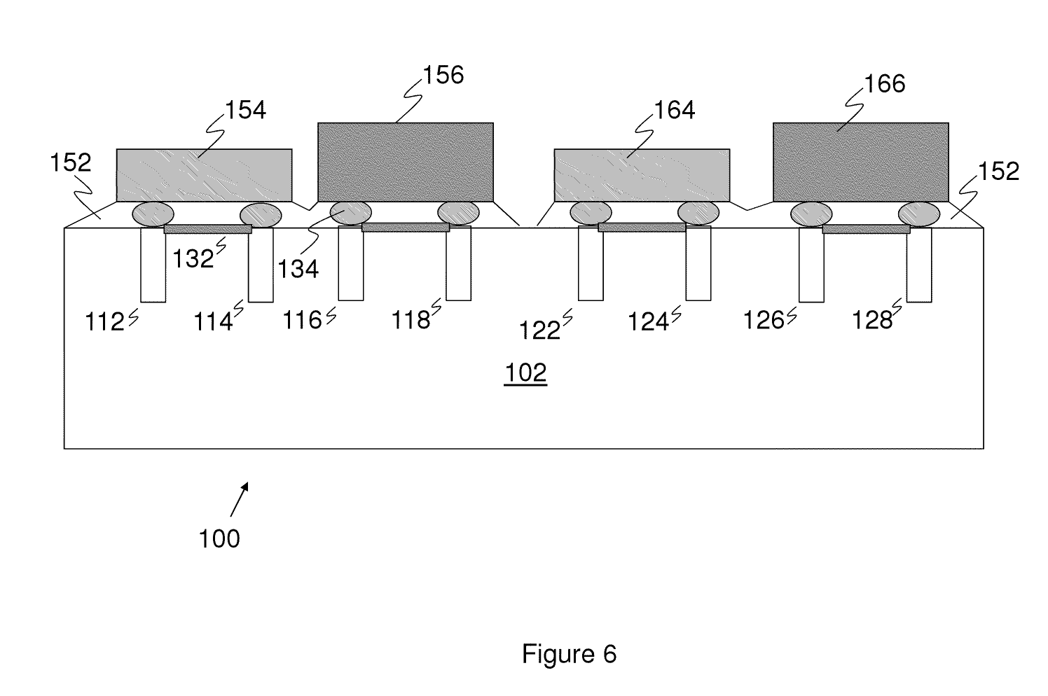

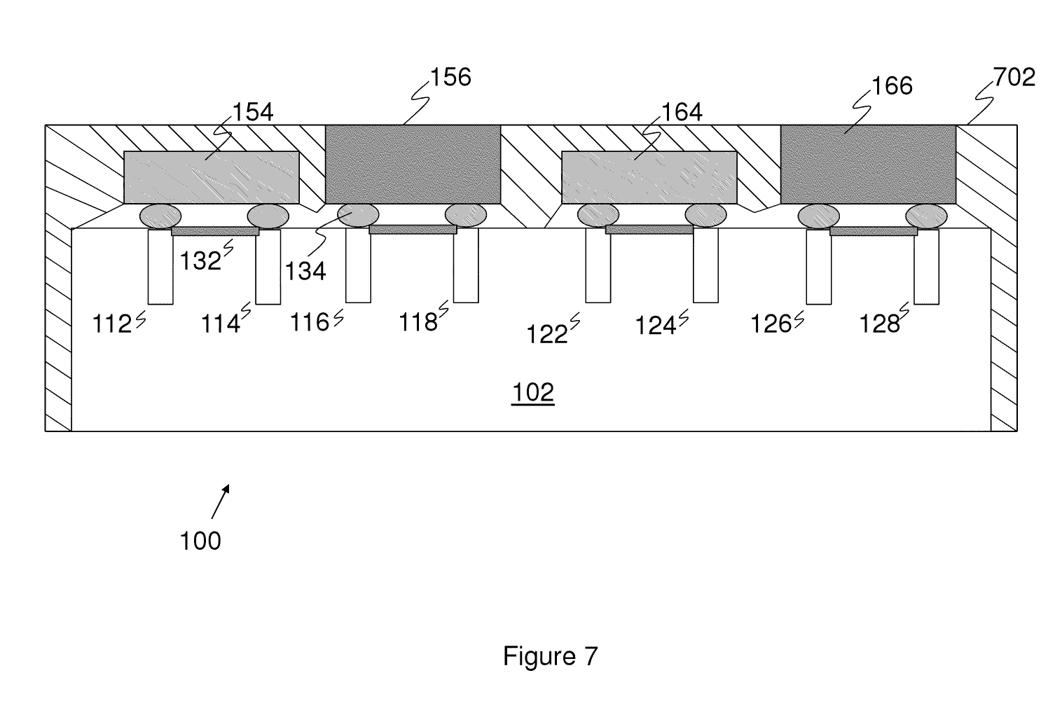

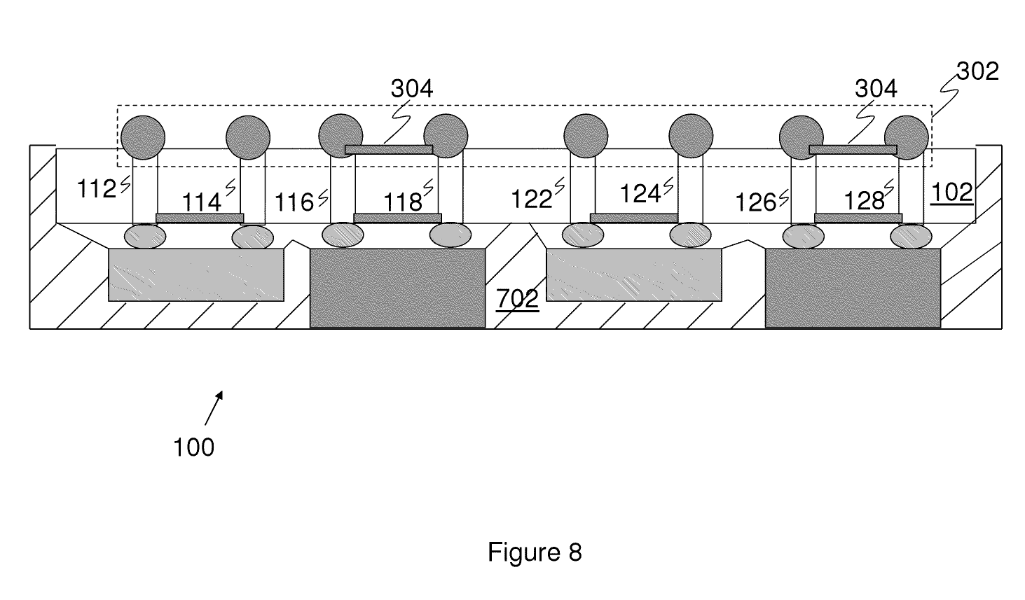

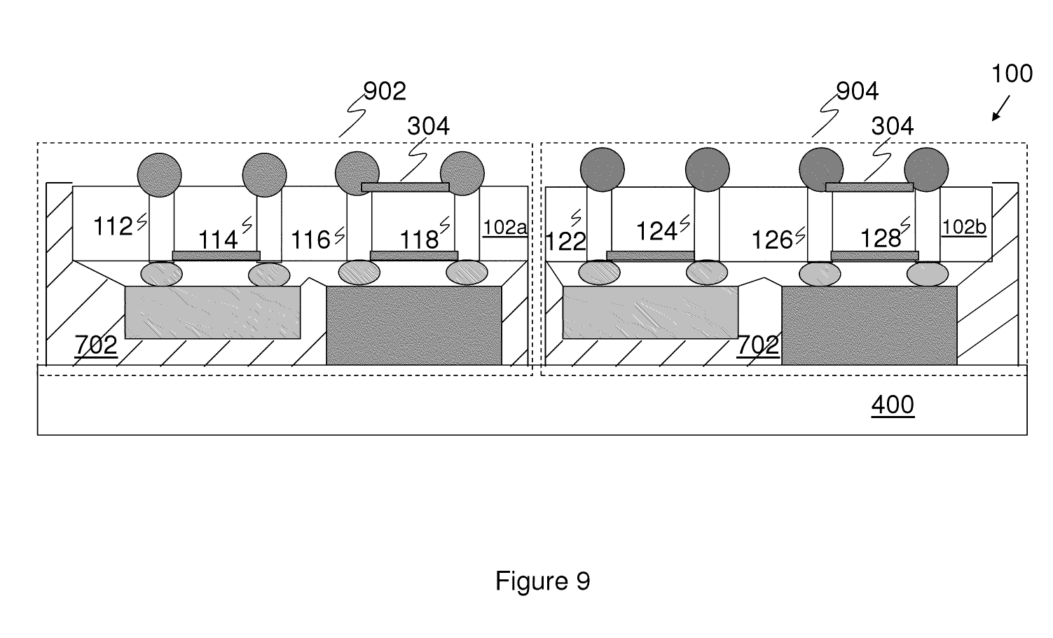

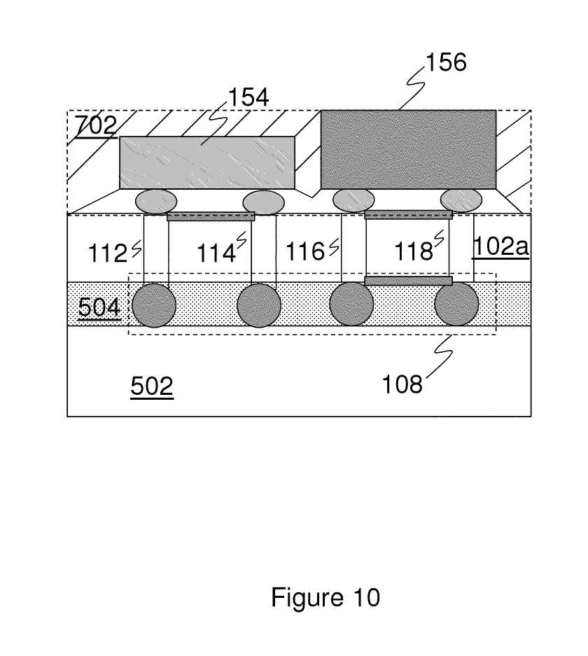

FIGS. 6-10 are cross sectional views of intermediate stages in the making of a 3D IC in accordance with another embodiment. FIGS. 6-10 are similar to FIGS. 1-5 except that the molding compound layer 702 in FIG. 7 is extended to cover the edge of the wafer 102. In order to protect the edge of the wafer 102 during process steps such as dicing the wafer stack 100 into separate chip packages, the molding compound layer 702 is employed to keep the edge from cracking. The process of forming the molding compound layer 702 is similar to that of forming the molding compound layer 202, and hence is not discussed in further detail to avoid unnecessary repetition. The process procedures of grinding the backside of the wafer 102, attaching the wafer stack 100 to a tape frame 400 and sawing the wafer stack 100 into a plurality of individual packages have been described with respect to FIGS. 3-5, and hence are not discuss again to avoid repetition.

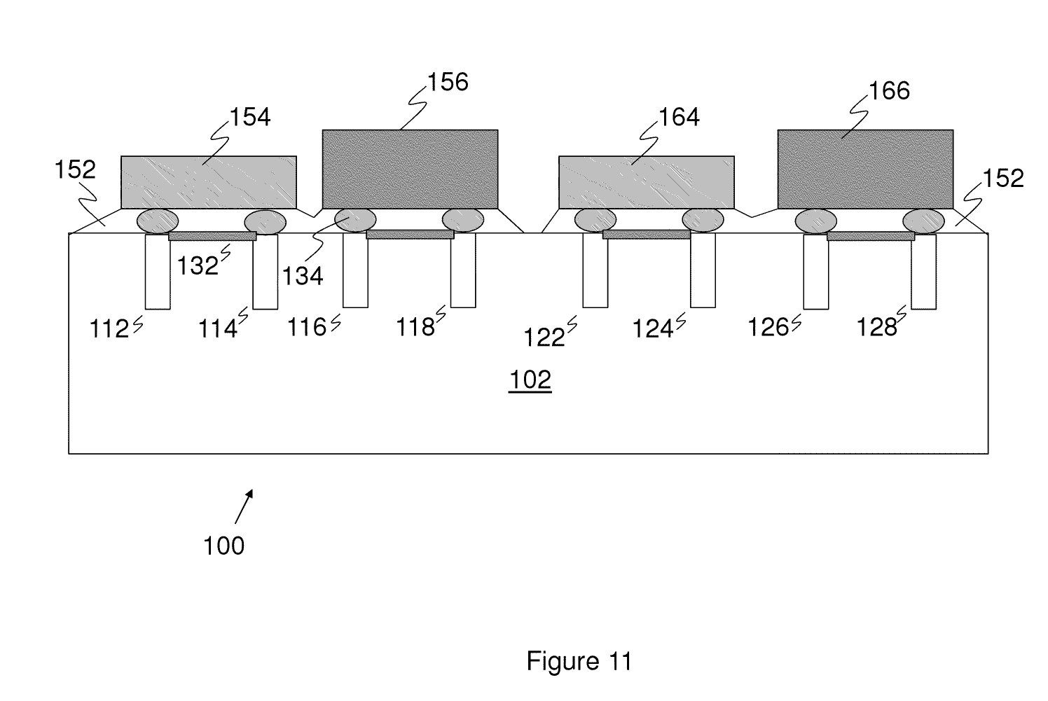

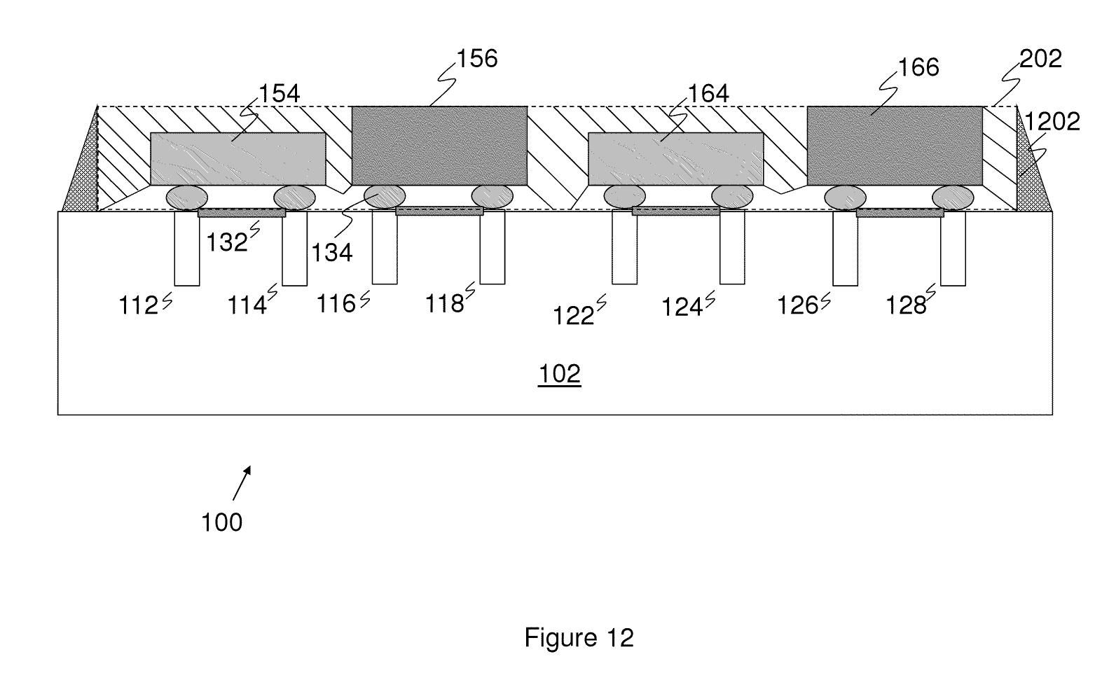

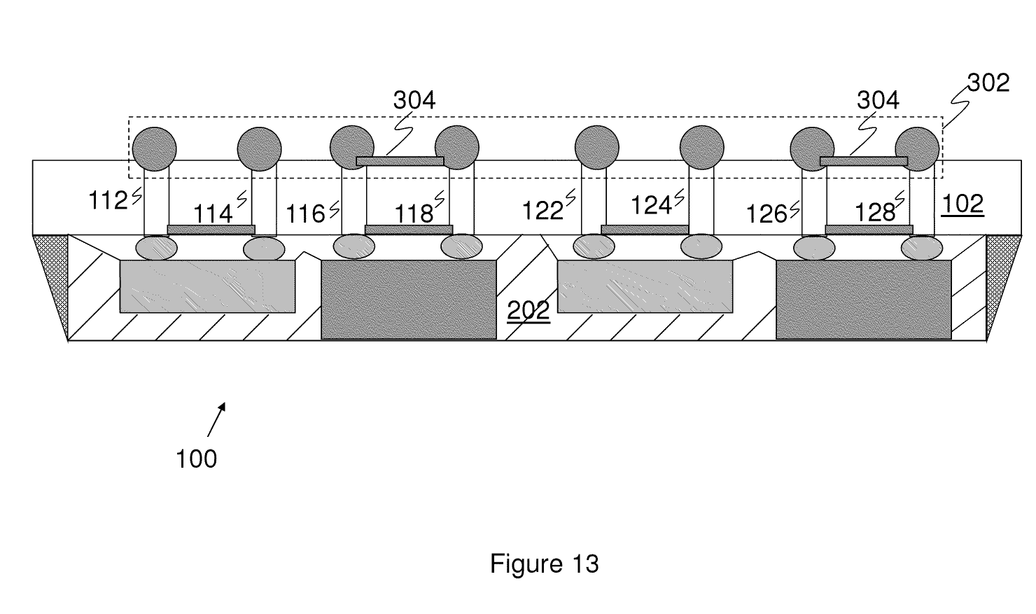

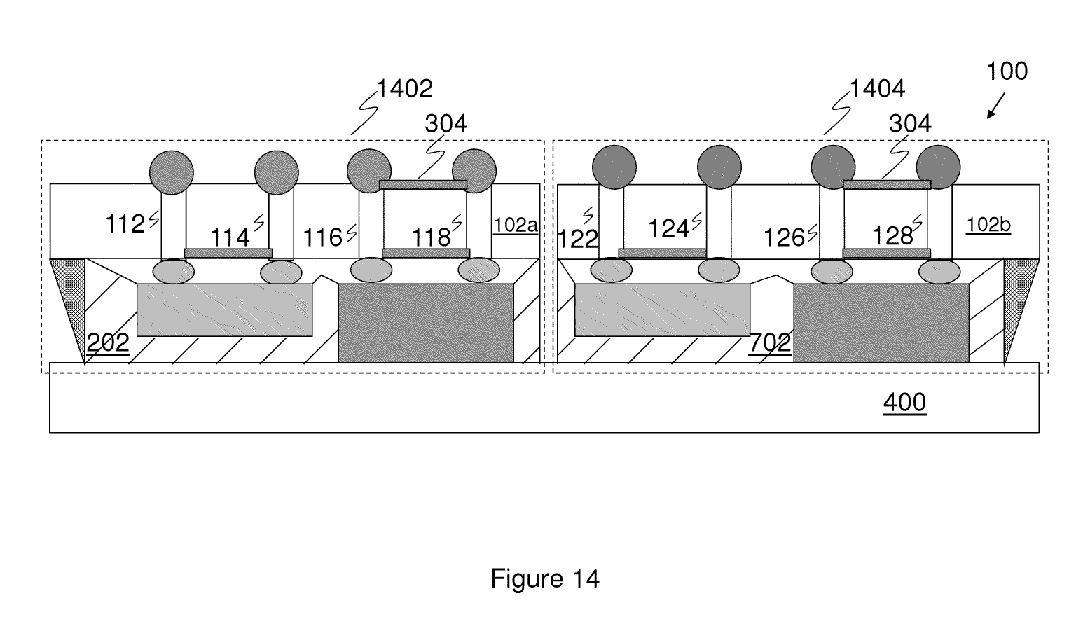

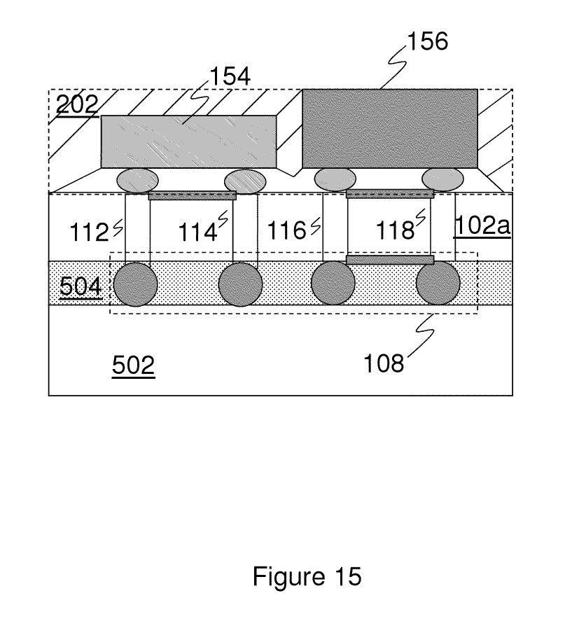

FIGS. 11-15 are cross sectional views of intermediate stages in the making of a 3D IC in accordance with yet another embodiment. FIGS. 11-15 are similar to FIGS. 1-5 except that an additional protection material 1202 are formed between the edge of the molding compound layer 202 and the edge of the wafer 102. In order to protect the edge of the wafer 102 during process steps such as dicing the wafer into separate chip packages, the molding compound layer 702 is employed to keep the edges from cracking. In addition, an additional protection material 1202 is employed to provide a cushion region absorbing mechanical and thermal stresses during the process of fabricating the 3D IC. The additional protection material 1202 may be formed by dispensing, laminating and/or printing the additional protection material between the edge of the molding compound layer 202 and the edge of the wafer 102. In accordance with an embodiment, the protection material 1202 may a polymer material such as polyimide (PI), epoxy and/or the like. The process procedures of grinding the backside of the wafer 102, attaching the wafer stack 100 to a tape frame 400 and sawing the wafer stack 100 into a plurality of individual packages have been described with respect to FIGS. 3-5, and hence are not discuss again to avoid repetition.

In accordance with an embodiment, a method comprises providing a wafer stack wherein a plurality of semiconductor dies are mounted on a first side of a first semiconductor die, forming a molding compound layer on the first side of the first semiconductor die, wherein the plurality of semiconductor dies are embedded in the molding compound layer. The method further comprises thinning a second side of the first semiconductor die until a plurality of through vias become exposed, attaching the wafer stack to a tape frame and dicing the wafer stack to separate the wafer stack into a plurality of individual packages.

In accordance with another embodiment, a method comprises providing a wafer stack wherein a plurality of semiconductor dies are mounted on a first side of a first semiconductor die, forming a molding compound layer on the first side of the first semiconductor die, wherein the plurality of semiconductor dies are embedded in the first molding compound layer and extending the molding compound layer covering an outer edge of the first semiconductor die. The method further comprises thinning a second side of the first semiconductor die until a plurality of through vias become exposed, attaching the wafer stack to a tape frame and dicing the wafer stack to separate the wafer stack into a plurality of individual packages.

In accordance with yet another embodiment, a structure comprises a substrate layer and a first semiconductor die mounted on the substrate layer. The first semiconductor die comprises a plurality of bumps on a first side of the first semiconductor die, a plurality of micro bumps on a second side of the first semiconductor die and a redistribution layer formed on top of the second side of the first semiconductor die. The structure further comprises a plurality of semiconductor dies mounted on top of the second side of the first semiconductor die.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method comprising:
providing a stack wherein a plurality of semiconductor dies are mounted on a first side of a wafer;
forming a molding compound layer on the first side of the wafer, wherein the plurality of semiconductor dies are embedded in the molding compound layer;
thinning a second side of the wafer until a plurality of through vias become exposed;
attaching the stack to a tape frame; and
dicing the stack to separate the stack into a plurality of individual packages.

2. The method of claim 1, further comprising:
forming a first underfill layer between the wafer and the plurality of semiconductor dies.

3. The method of claim 1, further comprising:
forming the plurality of through vias in the wafer;
forming a plurality of first bumps on the first side of the wafer; and
forming a first redistribution layer on the first side of the wafer.

4. The method of claim 3, wherein the plurality of semiconductor dies are connected to the wafer through the plurality of first bumps and the first redistribution layer.

5. The method of claim 1, further comprising:
forming a plurality of second bumps on the second side of the wafer; and
forming a second redistribution layer on the second side of the wafer.

6. The method of claim 1, further comprising:
detaching each individual package from the tape frame.

7. The method of claim 6, further comprising:
attaching the individual package on a substrate.

8. The method of claim 1, further comprising:
forming a protection layer between an outer edge of the molding compound layer and an outer edge of the stack.

9. A method comprising:
providing a stack wherein a plurality of semiconductor dies are mounted on a first side of a wafer, wherein the wafer comprises a plurality of through vias;
forming a molding compound layer on the first side of the wafer, wherein the plurality of semiconductor dies are embedded in the first molding compound layer;
extending the molding compound layer covering an outer edge of the wafer;
thinning a second side of the wafer to expose the plurality of through vias;
attaching the stack to a tape frame; and
dicing the stack to separate the stack into a plurality of individual packages.

10. The method of claim 9, further comprising:
detaching each individual package from the tape frame; and
attaching the individual package to a substrate.

11. The method of claim 10, further comprising:
forming a first underfill layer between the wafer and the plurality of semiconductor dies; and
forming a second underfill layer between the individual package and the substrate.

12. The method of claim 9, further comprising:
cleaning a surface of the individual package; and
cleaning the outer edge of the wafer.

13. The method of claim 9, further comprising:
chemically polishing the second side of the wafer;
forming a second redistribution layer on the second side of the wafer; and
forming a plurality of bumps on the second side of the wafer.

14. The method of claim 13, further comprising:
forming a first redistribution layer on the first side of the wafer; and
forming a plurality of bumps electrically coupled to the first redistribution layer on the first side of the wafer.

15. A structure comprising:
a substrate; and
a stack mounted on the substrate comprising:
a plurality of semiconductor dies bonded on a first side of a die; and
a molding compound layer formed on the first side of the die and covering an outer edge of the die, wherein the plurality of semiconductor dies are embedded in the molding compound layer.

16. The structure of claim 15, further comprising a plurality of bumps formed between the substrate and the stack.

17. The structure of claim 15, wherein the plurality of semiconductor dies are coupled to the die using a plurality of first bumps.

18. The structure of claim 15, further comprising:
a first underfill layer formed between the plurality of semiconductor dies and the die; and
a second underfill layer formed between the die and the substrate.

19. The structure of claim 15, further comprising:
a plurality of through vias in the die.
